(19) United States
(12) Patent Application Publication
(10) Pub. No.: US 2020/0035719 A1
(43) Pub. Date: Jan. 30, 2020

(54) THIN-FILM TRANSISTOR SUBSTRATE, METHOD FOR MANUFACTURING THIN-FILM TRANSISTOR SUBSTRATE, AND DISPLAY DEVICE

(71) Applicant: Sharp Kabushiki Kaisha, Sakai City, Osaka (JP)

(72) Inventor: Shinya OHHIRA, Sakai City (JP)

(21) Appl. No.: 16/336,927

(22) PCT Filed: Sep. 21, 2017
(86) PCT No.: PCT/JP2017/033998

§ 371 Date: Mar. 27, 2019

(30) Foreign Application Priority Data
Sep. 28, 2016 (JP) 2016-189861

(51) Int. Cl. H01L 27/12; G02F 1/1333; G02F 1/1368; H01L 21/311

(52) U.S. Cl. CPC H01L 27/1248; G02F 1/133345; G02F 1/136227; H01L 27/1225; H01L 21/31111; G02F 1/1368

(57) ABSTRACT

A thin-film transistor substrate includes: an insulating substrate; a gate electrode disposed on the insulating substrate; a gate insulating layer that covers the gate electrode; an oxide-semiconductor layer that is disposed on the gate insulating layer and is partly over the gate electrode; an interlayer insulating layer that covers a top and a side of the oxide-semiconductor layer; and a source electrode and a drain electrode that are disposed on the interlayer insulating layer. The interlayer insulating layer includes first, second, and third interlayer insulating layers that are laminated on the oxide-semiconductor layer in this order, and includes a first opening where the source electrode is in contact with the oxide-semiconductor layer and a second opening where the drain electrode is in contact with the oxide-semiconductor layer in regions that are over the oxide-semiconductor layer in a plan view. Etch rates at which etching solution etches the first, second, and third interlayer insulating layers have certain relations.

### TECHNICAL FIELD

The present invention relates to a thin-film transistor substrate, a method for manufacturing a thin-film transistor substrate, and a display device. Specifically, the present invention relates to a thin-film transistor substrate that includes an etching-stopper layer on a semiconductor layer, a method for manufacturing the thin-film transistor substrate, and a display device that includes the thin-film transistor substrate.

### BACKGROUND ART

In a thin-film transistor substrate, each pixel as the smallest unit of an image is generally provided with a thin-film transistor (TFT) as a switching element. For example, a structure of the TFT is a bottom-gate structure in which a gate electrode, a gate insulating layer, and a semiconductor layer are laminated on a substrate in this order, and a source electrode and a drain electrode are disposed on the semiconductor layer.

In recent years, making the semiconductor layer of an oxide semiconductor has been considered because an oxide semiconductor has a high carrier-mobility, and semiconductor elements can be made smaller. For example, providing a thin-film transistor that includes a good interface between an oxide semiconductor and an insulating layer is considered in Patent Literature 1. Patent Literature 1 discloses that a gate insulating layer includes an insulating film that is made of amorphous silicon that contains at least O and N, and has such an oxygen-concentration distribution in a film-thickness direction that the oxygen concentration is high near the interface between the insulating film and the oxide-semiconductor layer and decreases with decreasing a distance to a gate electrode, thereby to stably manufacture TFTs that have good interface characteristics.

As one method for forming the source electrode and the drain electrode, a metal thin film is formed on the semiconductor layer, and then is patterned using wet etching. For example, disposing an etching-stopper layer on a semiconductor layer to protect the semiconductor layer from etching solution is considered in Patent Literature 2.

### CITATION LIST

### Patent Literature

Patent Literature 1: JP 2007-250982 A
Patent Literature 2: WO 2014/034617

### SUMMARY OF INVENTION

### Technical Problem

In a method for manufacturing a TFT that includes an interlayer insulating layer (etching-stopper layer), an interlayer insulating layer is formed on a semiconductor layer, and then a film of a conductive-line material, such as an aluminum (Al) film or a copper (Cu) film, is formed and patterned to form a source electrode and a drain electrode, for example. The source electrode and the drain electrode are patterned using wet etching in many cases because conductive lines are easily formed at relatively low cost.

The smaller an etch rate at which etching solution etches the interlayer insulating layer, the higher a resistant to the etching solution the interlayer insulating layer has. Therefore, the interlayer insulating layer that has a small etch rate is suitable to protect a semiconductor layer positioned under the source electrode and the drain electrode. On the other hand, according to studies of the inventors, if a thickness of the interlayer insulating layer is increased, for example, to improve etch resistance of the interlayer insulating layer, membrane stress increases and film adhesion decreases in some cases. If the interlayer insulating layer does not cover steps well, cracks appear in the interlayer insulating layer or the interlayer insulating layer peels off in some cases. Consequently, during formation of conductive lines, etching solution reaches the semiconductor layer from steps of sides of the semiconductor layer. Especially if the semiconductor layer is formed of an oxide semiconductor, etching solution etches the oxide semiconductor, and consequently characteristics of the transistor are not stable in some cases. Therefore, it is difficult to form an interlayer insulating layer that has a high resistance to etching solution, while reducing the membrane stress.

The present invention has been made in view of such a current state of the art and aims to provide a reliable thin-film transistor substrate, a method for manufacturing the thin-film transistor substrate, and a display device.

### Solution to Problem

For example, a TFT that includes an etching-stopper (ES) layer has such a configuration as in Comparative Embodiment 1 illustrated in FIGS. 15 and 16 in which an ES layer 315 is island-shaped and is formed only over a channel region of an oxide-semiconductor layer 14 (hereinafter also referred to as an island-shaped ES-TFT), or such a configuration as in Embodiment 1 illustrated in FIGS. 2 and 3 in which an ES layer 15 is formed on a whole surface of an oxide-semiconductor layer 14 except a first opening 18 and a second opening 19 that are contact holes where the ES layer 15 is etched (hereinafter also referred to as a sheet-shaped ES-TFT), for example. In the island-shaped ES-TFT, the ES layer does not cover other regions than the channel region of the oxide-semiconductor layer 14. Therefore, in some cases, etching solution reaches the oxide-semiconductor layer 14 when the source electrode and the drain electrode are formed. On the other hand, in the sheet-shaped ES-TFT, the ES layer is formed on a whole surface of the oxide-semiconductor layer 14. Therefore, it is difficult for etching solution to reach the oxide-semiconductor layer 14. If sides of the oxide-semiconductor layer 14 are not covered sufficiently, however, etching solution reaches and removes the oxide-semiconductor layer 14 in some cases.

The inventors have further studied configurations of the sheet-shaped ES-TFT, and have found that an interlayer insulating layer that includes three layers is disposed between an oxide-semiconductor layer, and a source electrode and a drain electrode, and an etch rate ER1 at which etching solution etches a first interlayer insulating layer, an etch rate ER2 at which etching solution etches a second interlayer insulating layer, and an etch rate ER3 at which etching solution etches a third interlayer insulating layer are made to have relations of ER2<ER1 and ER3 ER1. Consequently, the interlayer insulating layer has a resistance to etching solution, while membrane stress is reduced. Therefore, etching solution is prevented from reaching the oxide-semiconductor layer from sides that form steps that are difficult to cover when the source electrode and the drain electrode are formed. Thereby, the inventors have arrived at the solution to the above problem, completing the present invention.

One aspect of the present invention may be a thin-film transistor substrate that includes: an insulating substrate; a gate electrode disposed on the insulating substrate; a gate insulating layer that covers the gate electrode; an oxide-semiconductor layer that is disposed on the gate insulating layer and is partly over the gate electrode; an interlayer insulating layer that covers a top and a side of the oxide-semiconductor layer; and a source electrode and a drain electrode that are disposed on the interlayer insulating layer, wherein the interlayer insulating layer includes a first interlayer insulating layer, a second interlayer insulating layer, and a third interlayer insulating layer that are laminated on the oxide-semiconductor layer in this order, and includes a first opening where the source electrode is in contact with the oxide-semiconductor layer and a second opening where the drain electrode is in contact with the oxide-semiconductor layer in regions that are over the oxide-semiconductor layer in a plan view, and an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

Another aspect of the present invention may be a display device that includes a thin-film transistor substrate according to the present invention.

Another aspect of the present invention may be a method for manufacturing a thin-film transistor substrate that has a bottom-gate structure, including the steps of: forming an interlayer insulating layer on an oxide-semiconductor layer; and forming a source electrode and a drain electrode on the interlayer insulating layer, wherein in the forming the interlayer insulating layer, a first interlayer insulating layer is formed to cover the oxide-semiconductor layer, a second interlayer insulating layer is formed on the first interlayer insulating layer, and a third interlayer insulating layer is formed on the second interlayer insulating layer, and part of the first, second, and third interlayer insulating layers is removed at regions that are over the oxide-semiconductor layer in a plan view to form a first opening and a second opening, and in the forming the source electrode and the drain electrode, a conductive film is formed on the interlayer insulating layer, the first opening, and the second opening, and is patterned using wet etching, and an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

### Advantageous Effects of Invention

According to the present invention, an interlayer insulating layer that includes three layers is disposed on an oxide-semiconductor layer, and etching solution etches the three layers at respective etch rates that have special relations. Consequently, resistance to etching solution and reduction of membrane stress are both achieved, and elimination of the oxide-semiconductor layer by reaching of etching solution to the oxide-semiconductor layer is prevented. Therefore, a reliable thin-film transistor substrate, a method for manufacturing the thin-film transistor substrate, and a reliable display device that includes the thin-film transistor substrate can be provided.

### BRIEF DESCRIPTION OF DRAWINGS

FIG. 1 is a schematic plan view that illustrates a whole TFT substrate according to Embodiment 1.

FIG. 2 is a schematic plan view of one pixel of a TFT substrate according to Embodiment 1 and Example 1.

FIG. 3 is a schematic cross-sectional view taken along line A-B in FIG. 2.

FIG. 4 is a schematic view that illustrates a step of manufacturing the TFT substrate according to Embodiment 1, and is a schematic cross-sectional view that illustrates a step of forming a gate electrode on an insulating substrate.

FIG. 5 is a schematic view that illustrates a step of manufacturing the TFT substrate according to Embodiment 1, and is a schematic cross-sectional view that illustrates a step of forming a gate insulating layer on a gate electrode.

FIG. 6 is a schematic view that illustrates a step of manufacturing the TFT substrate according to Embodiment 1, and is a schematic cross-sectional view that illustrates a step of forming an oxide-semiconductor layer on a gate insulating layer.

FIGS. 7(a) to 7(d) are schematic views that illustrate a step of manufacturing the TFT substrate according to Embodiment 1, and are schematic cross-sectional views that illustrate a step of forming an interlayer insulating layer on an oxide-semiconductor layer.

FIGS. 8(a) and 8(b) are schematic views that illustrate a step of manufacturing the TFT substrate according to Embodiment 1, and are schematic cross-sectional views that illustrate a step of forming a source electrode and a drain electrode on an interlayer insulating layer.

FIGS. 9(a) to 9(c) are schematic views that illustrate a step of manufacturing the TFT substrate according to Embodiment 1, and are schematic cross-sectional views that illustrate a step of forming a common electrode.

FIGS. 10(a) and 10(b) are schematic views that illustrate a step of manufacturing the TFT substrate according to Embodiment 1, and are schematic cross-sectional views that illustrate a step of forming a pixel electrode.

FIG. 11 is a schematic plan view around a TFT of the TFT substrate according to Variation 1.

FIG. 12 is a schematic cross-sectional view taken along line C-D in FIG. 11.

FIG. 13 is a schematic cross-sectional view of a boundary between a display region and a peripheral region of a TFT substrate according to Embodiment 2.

FIG. 14 is a schematic cross-sectional view that illustrates one example of a display device according to the present invention.

FIG. 15 is a schematic plan view around a TFT of a TFT substrate according to Comparative Embodiment 1.

FIG. 16 is a schematic cross-sectional view taken along line E-F in FIG. 15.

### DESCRIPTION OF EMBODIMENTS

Hereinafter, embodiments of the present invention will be described. The embodiments are not intended to limit the scope of the present invention, and design of the embodiments may appropriately be modified within a scope that satisfies a configuration of the present invention. The same reference signs in different drawings denote the same portions and portions that have similar functions. In the description below, explanation for such portions will not be repeated. The configurations of the embodiments may appropriately be combined or modified within the spirit of the present invention.

### Embodiment 1

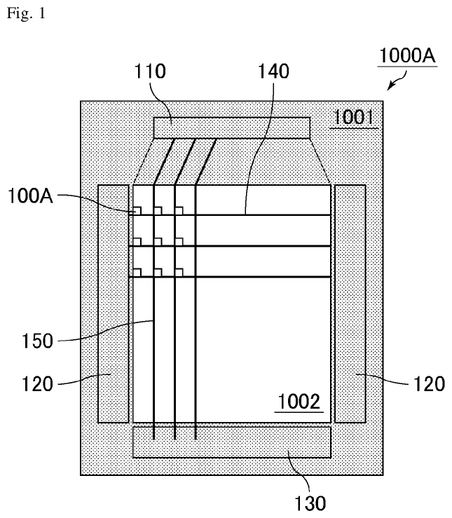

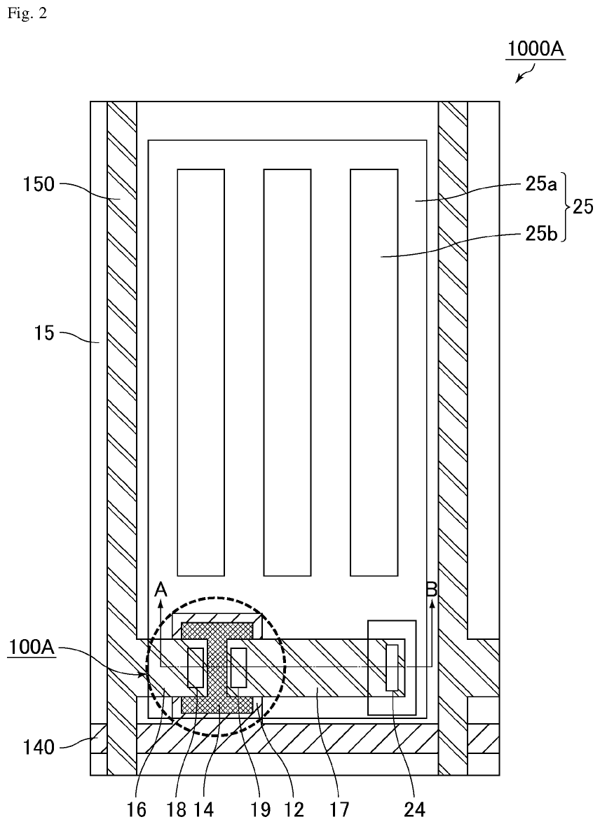

With reference to FIGS. 1 to 3, a thin-film transistor (TFT) substrate according to Embodiment 1 will be described. A TFT substrate 1000A according to Embodiment 1 is a TFT substrate driven by active matrix technology. FIG. 1 is a schematic plan view that illustrates the whole TFT substrate according to Embodiment 1. FIG. 2 is a schematic plan view of one pixel of the TFT substrate according to Embodiment 1. FIG. 3 is a schematic cross-sectional view taken along line A-B in FIG. 2.

As illustrated in FIG. 1, the TFT substrate 1000A includes a display region 1002 that includes multiple pixels, and a region except the display region 1002 (non-display region 1001). The non-display region 1001 includes a drive circuit formation region that includes drive circuits. The drive circuit formation region includes a source driver circuit 110, a gate driver circuit 120, and an inspection circuit 130, for example. The display region 1002 includes multiple gate bus lines 140 that extend in a row direction, and multiple source bus lines 150 that extend in a column direction. The gate bus lines 140 are connected to terminals of the gate driver circuit 120, respectively. The source bus lines 150 are connected to terminals of the source driver circuit 110, respectively. Each pixel corresponds to a region surrounded by the gate bus lines 140 and the source bus lines 150. Each pixel includes a thin-film transistor (TFT) 100A as a switching element.

As illustrated in FIG. 2, the TFT 100A includes an oxide-semiconductor layer 14, a drain electrode 17, a gate electrode 12 connected to one of the gate bus lines 140, and a source electrode 16 connected to one of the source bus lines 150. The oxide-semiconductor layer 14 is partly over the gate electrode 12. A region between the source electrode 16 and the drain electrode 17 is a channel region. A first opening 18 and a second opening 19 are formed in regions over the oxide-semiconductor layer 14 in a plan view. A region except the first opening 18 and the second opening 19 is covered by an interlayer insulating layer 15. The interlayer insulating layer 15 is an etching-stopper layer, and protects the oxide-semiconductor layer 14 when the source electrode 16 and the drain electrode 17 are formed on the oxide-semiconductor layer 14. Each pixel includes a pixel electrode 25.

As illustrated in FIG. 3, the TFT 100A has a bottom-gate structure. The TFT substrate 1000A includes an insulating substrate 11, the gate electrode 12 disposed on the insulating substrate 11, a gate insulating layer 13 that covers the gate electrode 12, the oxide-semiconductor layer 14 that is disposed on the gate insulating layer 13 and is partly over the gate electrode 12, the interlayer insulating layer 15 that covers a top and sides of the oxide-semiconductor layer 14, and the source electrode 16 and the drain electrode 17 that are disposed on the interlayer insulating layer 15. The source electrode 16 is in contact with the oxide-semiconductor layer 14 at the first opening 18. The drain electrode 17 is in contact with the oxide-semiconductor layer 14 at the second opening 19. A first inorganic insulating film 20 and an organic insulating layer 21 are disposed on the source electrode 16 and the drain electrode 17. A pixel electrode 25 is disposed over the organic insulating layer 21. A base layer may be disposed between the insulating substrate 11 and the gate electrode 12.

The TFT substrate 1000A according to Embodiment 1 may be used in a liquid crystal display device that uses Fringe Field Switching (FFS) mode that is a type of horizontal alignment mode. If the TFT substrate 1000A is used for FFS mode, the TFT substrate 1000A also has an FFS electrode structure in which a sheet-shaped electrode (common electrode 22), a second inorganic insulating film 23, and a slit electrode (the pixel electrode 25) are laminated on the organic insulating layer 21. The pixel electrode 25 is in contact with the drain electrode 17 at a third opening 24 that extends through the first inorganic insulating film 20, the organic insulating layer 21, and the second inorganic insulating film 23.

The insulating substrate 11 may be a general insulating substrate for a display, such as a glass substrate, a silicon substrate, or a heat-resist plastic substrate. Materials for the plastic substrate include polyethylene terephthalate resin, polyethylene naphthalate resin, polyethersulfone resin, acrylic resin, and polyimide resin, for example.

The gate electrode 12 may be a film that contains molybdenum (Mo), titanium (Ti), aluminum (Al), copper (Cu), tungsten (W), tantalum (Ta), or chromium (Cr), or an alloy or a nitride of molybdenum (Mo), titanium (Ti), aluminum (Al), copper (Cu), tungsten (W), tantalum (Ta), or chromium (Cr), for example. The gate electrode may be a laminated film in which multiple kinds of films are laminated. A thickness of the gate electrode is 100 to 800 nm, for example.

The gate insulating layer 13 may be a silicon oxide (SiO₂) film, a silicon nitride (SiNx) film, or a silicon oxide nitride (SiOxNy) film, for example. In view of decrease in oxygen deficiency of the oxide-semiconductor layer, the gate insulating layer 13 preferably contains silicon oxide, especially SiO₂. The gate insulating layer may be a single layer, or multiple layers. A thickness of the gate insulating layer is 20 to 50 nm, for example.

The oxide-semiconductor layer 14 is disposed on the gate insulating layer 13 and is partly over the gate electrode 12. The oxide-semiconductor layer 14 contains an oxide semiconductor. An oxide semiconductor increases electron mobility of a TFT, compared with amorphous silicon. Therefore, a sufficient voltage is applied to a liquid crystal layer even if definition of a display device is high, that is, even if a TFT of each pixel is on for a short time. An oxide semiconductor also decreases leakage current when a TFT is off, compared with amorphous silicon. Whether definition is high or not, low-frequency drive or drive that includes sleep mode is employed, and thus power consumption is reduced. A thickness of the oxide-semiconductor layer 14 is 30 to 100 nm, for example.

The oxide semiconductor contains oxygen (O) and at least one element selected from a group consisting of indium (In), gallium (Ga), aluminum (Al), copper (Cu), zinc (Zn), magnesium (Mg), cadmium (Cd), titanium (Ti), and germanium (Ge). The oxide-semiconductor layer preferably contains a semiconductor that contains indium, gallium, zinc, and oxygen (In-Ga—Zn-O semiconductor), a semiconductor that contains zinc and oxygen (Zn—O semiconductor), a semiconductor that contains indium, zinc, and oxygen (In—Zn—O semiconductor), a semiconductor that contains zinc, titanium, and oxygen (Zn—Ti—O semiconductor), a semiconductor that contains cadmium, germanium, and oxygen (Cd—Ge—O semiconductor), a semiconductor that contains cadmium, lead, and oxygen (Cd—Pb—O semiconductor), a semiconductor that contains cadmium oxide, a semiconductor that contains magnesium, zinc, and oxygen (Mg—Zn—O semiconductor), a semiconductor that contains indium, tin, zinc, and oxygen (In—Sn—Zn—O semiconductor, such as In₂O₃—SnO₂—ZnO), or a semiconductor that contains indium, gallium, tin, and oxygen (In—Ga—Sn—O semiconductor). The oxide-semiconductor layer more preferably contains a semiconductor that contains indium, gallium, zinc, and oxygen. The In-Ga—Zn-O semiconductor is an oxide that contains three elements of indium (In), Gallium (Ga), and zinc (Zn). A ratio (composition ratio) between In, Ga, and Zn is not specifically limited but may be In:Ga:Zn=2:2:1, In:Ga:Zn=1:1:1, or In:Ga:Zn=1:1:2, for example.

The interlayer insulating layer 15 covers a top and sides of the oxide-semiconductor layer 14. Consequently, etching solution does not reach the oxide-semiconductor layer 14 even if wet etching is used to form the source electrode 16 and the drain electrode 17 on the oxide-semiconductor layer 14. Therefore, the oxide-semiconductor layer 14 is not etched. The interlayer insulating layer 15 includes a first interlayer insulating layer 15a, a second interlayer insulating layer 15b, and a third interlayer insulating layer 15c that are laminated on the oxide-semiconductor layer 14 in this order. Since the interlayer insulating layer 15 has a three-layer structure, the etching solution is prevented from reaching the oxide-semiconductor layer 14, and the elimination of the oxide-semiconductor layer 14 is prevented. Therefore, a reliable TFT substrate is obtained.

An etch rate ER1 at which etching solution etches the first interlayer insulating layer 15a, an etch rate ER2 at which the etching solution etches the second interlayer insulating layer 15b, and an etch rate ER3 at which the etching solution etches the third interlayer insulating layer 15c have relations of ER2<ER1 and ER3≤ER1. The relations of ER2<ER1 and ER3≤ER1 improve etch resistance of the interlayer insulating layer 15 and reduce membrane stress. The etch rates ER1, ER2, and ER3 are etch rates of etching solution that contains a hydrogen-fluoride compound, for example. The etch rates are adjusted with types (composition), and thicknesses of the interlayer insulating layers, for example.

The etch rate ER2 at which the etching solution etches the second interlayer insulating layer 15b is lower than the etch rate ER1 at which the etching solution etches the first interlayer insulating layer 15a. Since a layer that is difficult to be etched is disposed on the first interlayer insulating layer 15a, the etching solution is prevented from reaching the oxide-semiconductor layer 14.

The etch rate ER3 at which the etching solution etches the third interlayer insulating layer 15c may be higher than the etch rate ER2 at which the etching solution etches the second interlayer insulating layer 15b, and may be equal to or lower than the etch rate ER1 at which the etching solution etches the first interlayer insulating layer 15a. That is, ER1, ER2, and ER3 may have a relation of ER2<ER3≤ER1. Further, the etch rate ER3 at which the etching solution etches the third interlayer insulating layer 15c may be lower than both the etch rate ER2 at which the etching solution etches the second interlayer insulating layer 15b and the etch rate ER1 at which the etching solution etches the first interlayer insulating layer 15a. That is, ER1, ER2, and ER3 may have a relation of ER3<ER2<ER1. Etch resistances of the interlayer insulating layers are adjusted with a combination of composition, film thicknesses, and etch rates of the interlayer insulating layers. ER2<ER3≤ER1 or ER3<ER2<ER1 for the etch rates of the interlayer insulating layers is appropriately selected with transistor characteristics, such as thresholds and off currents, materials and film-thickness composition of the source electrode and the drain electrode, and types of the etching solution.

If a silicon-oxide film (SiO₂), a silicon-oxide-nitride film (SiOxNy), and a silicon-nitride film (SiN) have the same thickness, a silicon-oxide film is generally etched at the highest etch rate by etching solution that contains a hydrogen-fluoride compound. A silicon-oxide-nitride film (SiOxNy (x:y=1:1)) is etched at a higher rate than a silicon-oxide-nitride film that contains more nitrogen (SiOxNy (x:y=1:2 to 5)). A silicon-oxide-nitride film that contains more nitrogen (SiOxNy (x:y=1:2 to 5)) is etched at a higher rate than a silicon-nitride film. A silicon-nitride film with an increased film thickness has an improved etch resistance but may reduce productivity if the silicon-nitride film is formed by CVD, for example. An increased proportion of silicon nitride in an interlayer insulating layer may decrease adhesion, and thus may decrease reliability of an oxide semiconductor. Therefore, a silicon-nitride film is preferably disposed apart from the oxide-semiconductor layer 14.

The first interlayer insulating layer 15a may contain silicon oxide (e.g. SiO₂). The first interlayer insulating layer 15a that contains silicon oxide effectively decreases oxygen deficiency of the oxide-semiconductor layer 14. The first interlayer insulating layer 15a preferably has a thickness of 10 nm to 100 nm. The thickness smaller than 10 nm may decrease insulation resistance. On the other hand, the thickness larger than 100 nm may decrease productivity. The first interlayer insulating layer 15a more preferably has a thickness of 20 nm to 80 nm.

The second interlayer insulating layer 15b may contain silicon nitride (e.g. SiN), silicon oxide nitride (e.g. SiOxNy (x:y=1:1)), or silicon oxide nitride that contains more nitrogen (e.g. SiOxNy (x:y=1:2 to 5)). The second interlayer insulating layer 15b preferably contains silicon oxide nitride (SiOxNy (x:y=1:1 or x:y=1:2 to 5)). An amount of nitrogen contained in silicon oxide nitride is adjusted using partial pressure of SiH₄ gas or ammonia gas, for example. If the second interlayer insulating layer 15b contains silicon oxide nitride that has a small membrane stress, the second interlayer insulating layer 15b has an increased thickness, and thus the etch rate is reduced without decrease in productivity. The second interlayer insulating layer 15b preferably has a thickness of 10 nm to 200 nm. The thickness smaller than 10 nm may decrease insulation resistance. On the other hand, the thickness larger than 200 nm may decrease productivity. The second interlayer insulating layer 15b more preferably has a thickness of 20 nm to 100 nm.

The third interlayer insulating layer 15c may contain silicon oxide (SiO₂), silicon nitride (SiNx), or silicon oxide nitride (SiOxNy (x:y=1:1)). If ER2<ER3≤ER1 is satisfied, the third interlayer insulating layer 15c may contain silicon oxide or silicon oxide nitride. If ER3<ER2<ER1 is satisfied, the third interlayer insulating layer 15c may contain silicon nitride or silicon oxide nitride. The third interlayer insulating layer 15c preferably has a thickness of 10 nm to 100 nm. The thickness smaller than 10 nm may decrease insulation resistance. On the other hand, the thickness larger than 100 nm may decrease productivity. The third interlayer insulating layer 15c more preferably has a thickness of 20 nm to 50 nm.

The interlayer insulating layer 15 preferably includes the first interlayer insulating layer 15a that contains silicon oxide, the second interlayer insulating layer 15b that contains silicon oxide nitride, and the third interlayer insulating layer 15c that contains silicon nitride. Alternatively, the interlayer insulating layer 15 preferably includes the first interlayer insulating layer 15a that contains silicon oxide, the second interlayer insulating layer 15b that contains silicon oxide nitride, and the third interlayer insulating layer 15c that contains silicon oxide nitride. Alternatively, the interlayer insulating layer 15 preferably includes the first interlayer insulating layer 15a that contains silicon oxide, the second interlayer insulating layer 15b that contains silicon oxide nitride, and the third interlayer insulating layer 15c that contains silicon oxide. If the second interlayer insulating layer 15b and the third interlayer insulating layer 15c each contain silicon oxide nitride, the second interlayer insulating layer 15b preferably contains more nitrogen than the third interlayer insulating layer 15c. Composition of the second interlayer insulating layer 15b is SiOxNy (x:y=1:2 to 5), for example. Composition of the third interlayer insulating layer 15c is SiOxNy (x:y=1:1), for example. However, as long as the second interlayer insulating layer 15b contains more nitrogen than the third interlayer insulating layer 15c, values y of SiOxNy contained in the second interlayer insulating layer 15b and the third interlayer insulating layer 15c are not specified.

The interlayer insulating layer 15 may include three or more layers. Another interlayer insulating layer, such as a silicon-oxide film, a silicon-nitride film, or a silicon-oxide-nitride film, may be laminated on the third interlayer insulating layer 15c.

The source electrode 16 and the drain electrode 17 may each be a film that contains molybdenum (Mo), titanium (Ti), aluminum (Al), copper (Cu), tungsten (W), tantalum (Ta), or chromium (Cr), or an alloy or a nitride of molybdenum (Mo), titanium (Ti), aluminum (Al), copper (Cu), tungsten (W), tantalum (Ta), or chromium (Cr), for example. The source electrode and the drain electrode may each be a laminated film in which multiple kinds of films are laminated. The source electrode 16 may include a source lower-layer electrode 16a, and a source upper-layer electrode 16b laminated on the source lower-layer electrode 16a. The drain electrode 17 may include a drain lower-layer electrode 17a, and a drain upper-layer electrode 17b laminated on the drain lower-layer electrode 17a. The source lower-layer electrode 16a and the drain lower-layer electrode 17a are each a Ti film with a thickness of 10 to 100 nm, for example. The source upper-layer electrode 16b and the drain upper-layer electrode 17b are each an Al film or a Cu film with a thickness of 100 to 500 nm, for example. Ti films used as the source lower-layer electrode 16a and the drain lower-layer electrode 17a improve adhesion between the interlayer insulating layer 15 and the source upper-layer electrode 16b and adhesion between the interlayer insulating layer 15 and the drain upper-layer electrode 17b.

The first inorganic insulating film 20 protects the channel region of the TFT 100A. The first inorganic insulating film 20 may be made of silicon oxide (e.g. SiO₂), silicon nitride (SiNx), or silicon oxide nitride (SiOxNy), for example. A thickness of the first inorganic insulating film 20 is not specifically limited, but is preferably 50 nm to 500 nm, and more preferably 100 nm to 300 nm. The first inorganic insulating film 20 may be an SiO₂ film with a thickness of 200 nm, for example.

The organic insulating layer 21 flattens the TFT substrate. The organic insulating film may be a photosensitive-resin film or a non-photosensitive-resin film, for example. The resin is specifically acrylic resin or photosensitive polyimide, for example. If a photosensitive-resin film is used as the organic insulating film, the organic insulating film is patterned by exposing the organic insulating film to light and developing the organic insulating film without formation of a resist. A thickness of the organic insulating layer 21 is not specifically limited, but is preferably 1 μm to 5 μm, and more preferably 2 μm to 4 μm. The organic insulating film may be a positive-photosensitive-acrylic-resin film with a thickness of 3 μm.

The common electrode 22 may be made of a translucent conductive material, for example. Specifically, the common electrode 22 may be made of indium-tin oxide (ITO), indium-zinc oxide (IZO), indium-tin oxide that contains silicon oxide (ITSO), indium oxide (In₂O₃), tin oxide (SnO₂), zinc oxide (ZnO), or titanium nitride (TiN), for example. A first transparent conductive film may be a laminated film in which multiple kinds of films are laminated. The common electrode 22 may be an ITO film with a thickness of 100 nm.

The second inorganic insulating film 23 is disposed between the common electrode 22 and the pixel electrode 25, and functions as an insulator that insulates the common electrode 22 from the pixel electrode 25, and also functions as a dielectric that forms a storage capacitor. The second inorganic insulating film 23 can be made of silicon oxide (e.g. SiO₂), silicon nitride (SiNx), or silicon oxide nitride (SiOxNy), for example. Silicon nitride (SiNx) is preferable because silicon nitride (SiNx) has excellent adhesion to a resin film and increases permittivity of the second inorganic insulating film 23. A thickness of the second inorganic insulating film 23 is not specifically limited, but is preferably 50 nm to 500 nm, and more preferably 100 nm to 300 nm. The second inorganic insulating film 23 may be a SiNx film with a thickness of 300 nm.

The pixel electrode 25 may be made of a translucent conductive material, for example. Specifically, the pixel electrode 25 may be made of indium-tin oxide (ITO), indium-zinc oxide (IZO), indium-tin oxide that contains silicon oxide (ITSO), indium oxide (In₂O₃), tin oxide (SnO₂), zinc oxide (ZnO), or titanium nitride (TiN), for example. The pixel electrode 25 may be a laminated film in which multiple kinds of films are laminated. The pixel electrode 25 may be an ITO film with a thickness of 100 nm.

If the TFT substrate 1000A according to Example 1 is a TFT substrate for FFS mode, the pixel electrode 25 is preferably a slit electrode that includes a line-shaped electrode and line-shaped openings (slits). As illustrated in FIG. 2, the slit electrode may include slits that are line-shaped openings 25b a whole periphery of each of which is surrounded by a line-shaped electrode 25a, for example. Alternatively, the slit electrode may be comb-shaped and include multiple comb-tooth-shaped portions and line-shaped slits disposed between the comb-tooth-shaped portions.

Hereinafter, a method for driving the TFT 100A will be described. Scanning signals are supplied to the gate bus lines 140 and the gate electrodes 12 from the gate driver circuit 120 in a pulse manner at predetermined times. The scanning signals are applied to each TFT 100A using progressive scanning method. Each input scanning signal switches on the TFT 100A for a predetermine period of time. When the TFT 100A is on, image signals are supplied to the pixel electrode 25 from the gate driver circuit 120 through the source bus line 150 and the TFT 100A. On the other hand, common signals that are commonly applied to all the pixels are supplied to the common electrode 22.

In the FFS mode, the pixel electrode 25 is laminated on the common electrode 22, and the second inorganic insulating film 23 is disposed between the pixel electrode 25 and the common electrode 22. When an image signal is applied to the pixel electrode 25, lines of electric force that are parabola-shaped and pass through the slits 25b of the pixel electrode 25 are generated between the pixel electrode 25 and the common electrode 22, and a fringe field that depends on the image signal is generated in a liquid crystal layer 1100. The fringe field controls alignment of liquid crystal molecules, and thus controls light transmittance of each pixel. In this way, the multiple pixels are separately driven, and an image is displayed on the display region 1002.

### Method for Manufacturing Thin-Film Transistor Substrate

A method for manufacturing a TFT substrate according to Embodiment 1 is a method for manufacturing a thin-film transistor substrate that has a bottom-gate structure, and includes a step of forming an interlayer insulating layer on an oxide-semiconductor layer, and a step of forming a source electrode and a drain electrode on the interlayer insulating layer. The method for manufacturing a TFT substrate according to Embodiment 1 may include a step of forming a gate electrode on an insulating substrate, and a step of forming a gate insulating layer on a gate electrode before the step of forming an interlayer insulating layer on an oxide-semiconductor layer.

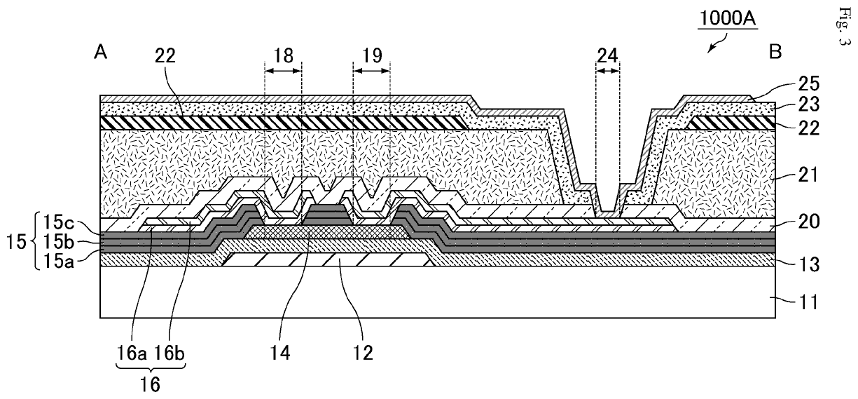

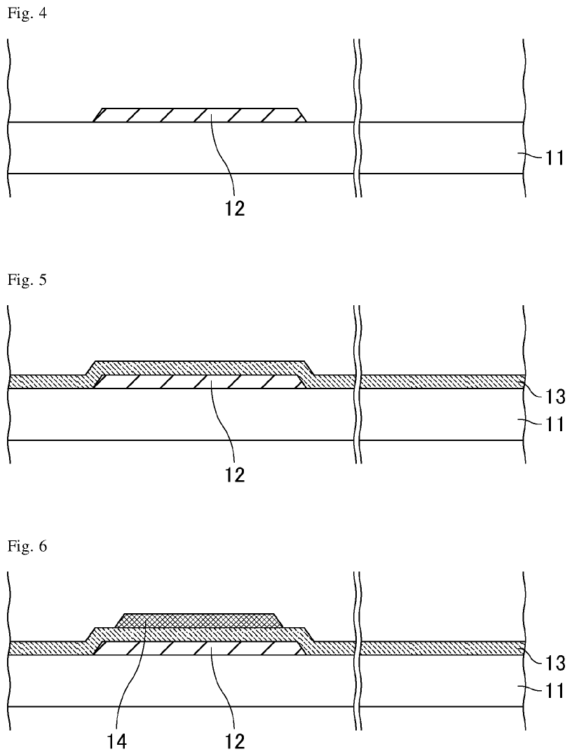

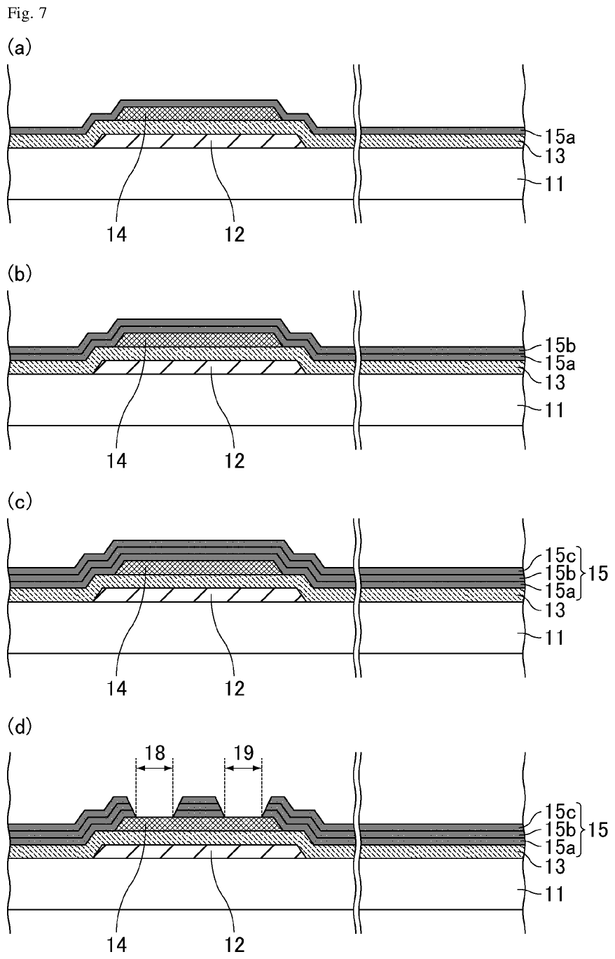

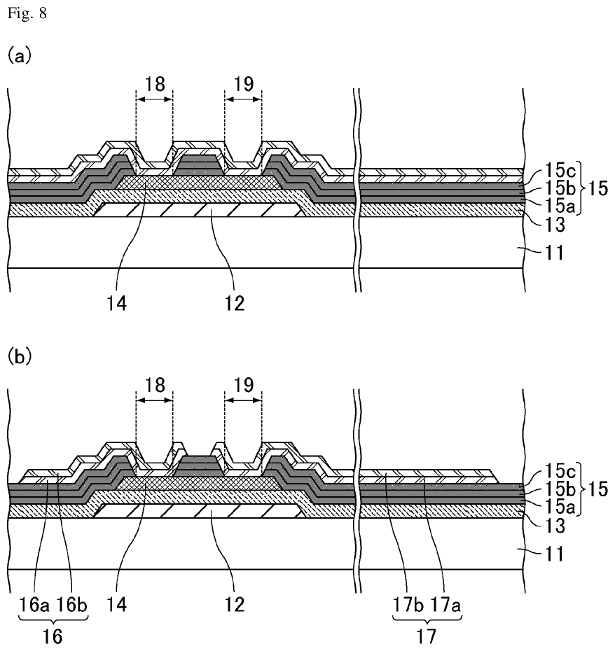

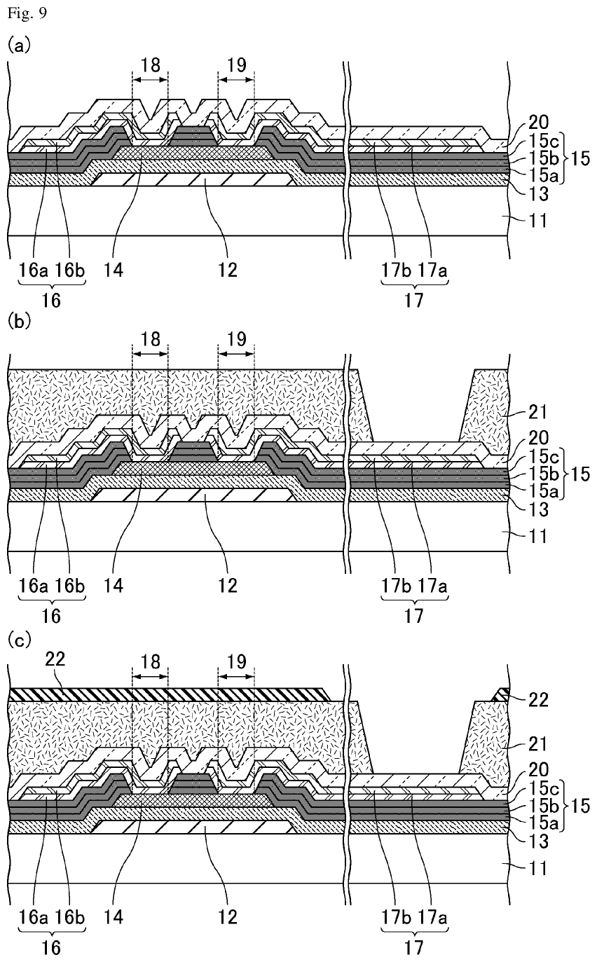

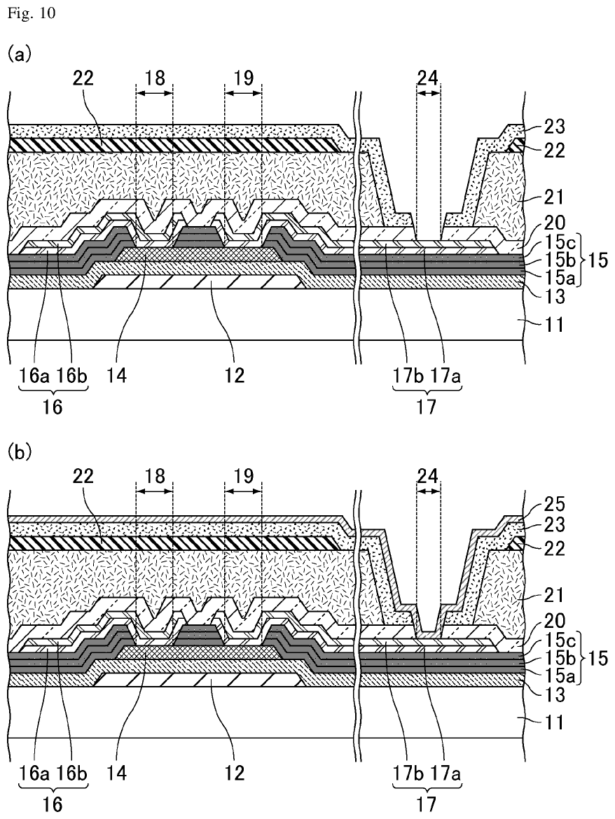

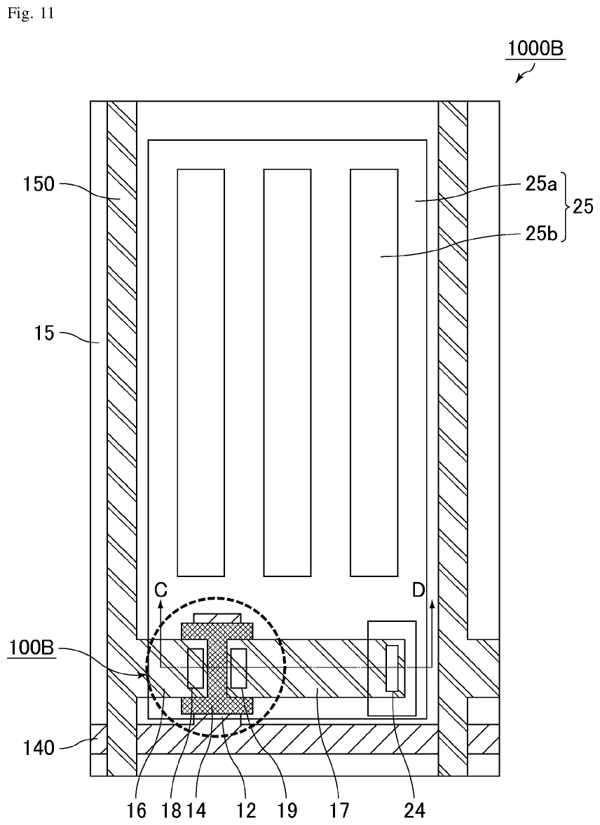

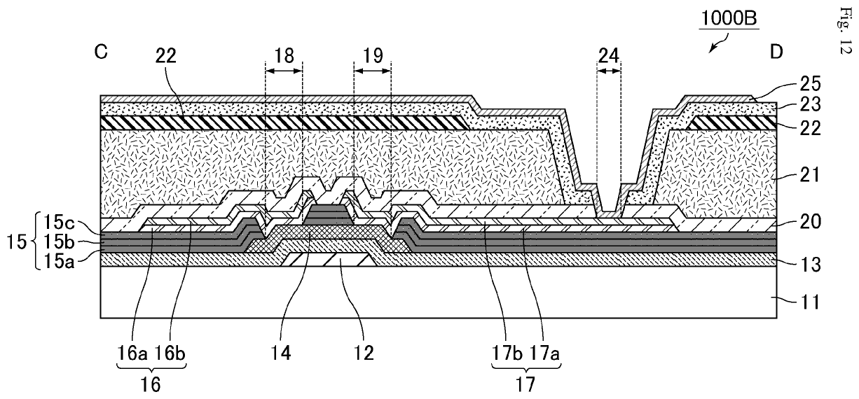

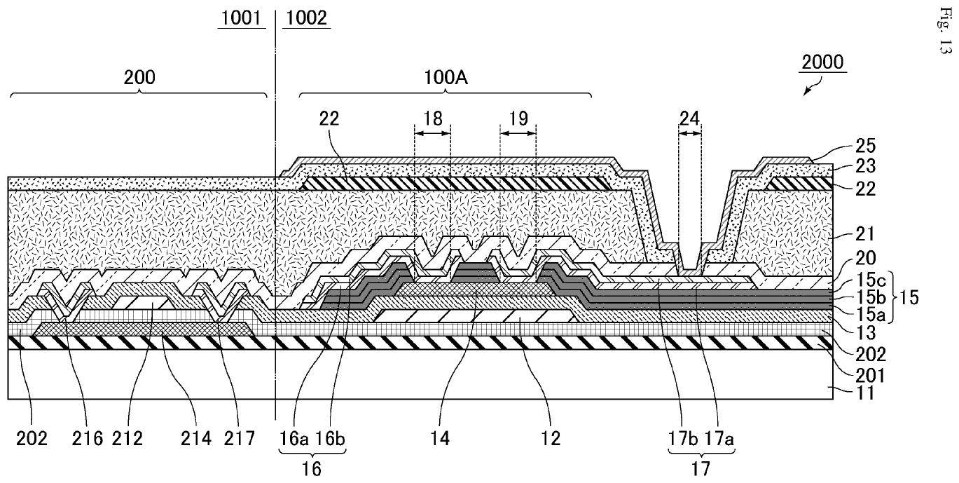

Hereinafter, the method for manufacturing a TFT substrate according to Embodiment 1 will be described referring to FIGS. 4 to 10. FIGS. 4 to 10 are each a schematic view that illustrates a step of manufacturing a TFT substrate according to Embodiment 1. FIG. 4 illustrates a step of forming a gate electrode on an insulating substrate. FIG. 5 illustrates a step of forming a gate insulating layer on a gate electrode. FIG. 6 illustrates a step of forming an oxide-semiconductor layer on a gate insulating layer. FIGS. 7(a) to 7(d) illustrate a step of forming an interlayer insulating layer on an oxide-semiconductor layer. FIGS. 8(a) and 8(b) illustrate a step of forming a source electrode and a drain electrode on an interlayer insulating layer. FIGS. 9(a) to 9(c) illustrate a step of forming a common electrode. FIGS. 10(a) and 10(b) illustrate a step of forming a pixel electrode.

In a step of forming a gate electrode 12 on an insulating substrate 11, an insulating substrate 11 is prepared, and a first conductive film is formed on a whole surface of the insulating substrate 11 using sputtering. Next, a first resist is formed on the first conductive film using photolithography. Next, the first resist is used as a mask and the first conductive film is wet-etched. The first resist is removed to form a gate electrode 12, as illustrated in FIG. 4. A gate bus line 140 is formed integrally with the gate electrode 12 but is not shown.

In a step of forming a gate insulating layer 13 on a gate electrode 12, a gate insulating layer 13 is formed on a whole surface of the substrate that includes the gate electrode 12 using chemical vapor deposition (CVD), as illustrated in FIG. 5.

In a step of forming an oxide-semiconductor layer 14 on a gate insulating layer 13, a semiconductor film is formed on a whole surface of the substrate that includes the gate insulating layer 13 using sputtering or CVD, for example. After the semiconductor film is formed, the semiconductor film may be annealed. After the semiconductor film is annealed, a second resist is formed on the semiconductor film using photolithography. The second resist is used as a mask and the semiconductor film is wet-etched. The second resist is removed to form an oxide-semiconductor layer 14 that is partly over the gate electrode 12, as illustrated in FIG. 6.

In a step of forming an interlayer insulating layer 15 on an oxide-semiconductor layer 14, first, a first interlayer insulating layer 15a is formed on a whole surface of the substrate that includes the oxide-semiconductor layer 14 using CVD, as illustrated in FIG. 7(a), such that the first interlayer insulating layer 15a covers the oxide-semiconductor layer 14. Next, a second interlayer insulating layer 15b is formed on the first interlayer insulating layer 15a using CVD, as illustrated in FIG. 7(b). Then a third interlayer insulating layer 15c is formed on the second interlayer insulating layer 15b using CVD, as illustrated in FIG. 7(c). Next, a third resist is formed on the third interlayer insulating layer 15c using photolithography. The third resist is used as a mask, and part of the first, second, and third interlayer insulating layers 15a, 15b, and 15c is dry-etched at regions that are over the oxide-semiconductor layer 14 in a plan view. Then the third resist is removed to form a first opening 18 and a second opening 19 in the regions that are over the oxide-semiconductor layer 14 in a plan view, as illustrated in FIG. 7(d).

The first, second, and third interlayer insulating layers 15a, 15b, and 15c may be formed using plasma CVD that uses SiH₄, N₂O, or O₂, or using CVD that uses tetraethoxysilane (TEOS) and O₂ or uses tetraethoxysilane (TEOS) and O₃. The first interlayer insulating layer 15a is preferably formed using CVD that uses TEOS and O₂ or uses TEOS and O₃. Using CVD that uses TEOS and O₂ or uses TEOS and O₃ forms an interlayer insulating layer that covers steps well. Forming the first interlayer insulating layer 15a using CVD that uses TEOS and O₂ or uses TEOS and O₃ allows a thin second interlayer insulating layer 15b and a thin third interlayer insulating layer 15c to be formed.

In a step of forming a source electrode 16 and a drain electrode 17 on an interlayer insulating layer 15, a conductive film (first transparent conductive film) is formed on the interlayer insulating layer 15, the first opening 18, and the second opening 19 using sputtering, as illustrated in FIG. 8(a). If the source electrode 16 and the drain electrode 17 each include multiple layers, a Ti film may be formed as a lower layer of the first transparent conductive film, and an Al film or a Cu film may be formed on the Ti film, for example. Next, a fourth resist is formed on the first transparent conductive film using photolithography. The fourth resist is used as a mask, and the first transparent conductive film is wet-etched. Then the fourth resist is removed to form the source electrode 16 and the drain electrode 17, as illustrated in FIG. 8(b). The source electrode 16 includes a source lower-layer electrode 16a and a source upper-layer electrode 16b laminated on the source lower-layer electrode 16a. The drain electrode 17 includes a drain lower-layer electrode 17a and a drain upper-layer electrode 17b laminated on the drain lower-layer electrode 17a.

In the step of forming the source electrode 16 and the drain electrode 17, wet etching may be performed using etching solution that contains a hydrogen-fluoride compound. The hydrogen-fluoride compound is hydrogen fluoride (HF) or ammonium fluoride (NH₄F), for example. If Al or Cu is used as the upper-layer electrodes of the source electrode 16 and the drain electrode 17, Ti films are often formed as the lower-layer electrodes. Since Ti films as lower layers need to be etched with etching solution with strong oxidizing power, the Ti films are preferably etched with the etching solution that contains a hydrogen-fluoride compound. A concentration of a hydrogen-fluoride compound in the etching solution is 0.01 to 0.5 mol %, for example. The etching solution that contains a hydrogen-fluoride compound has strong oxidizing power, and thus easily reaches and removes the oxide-semiconductor layer 14. Accordingly, due to a three-layer structure of the interlayer insulating layer 15 when the etching solution that contains a hydrogen-fluoride compound is used, elimination of the oxide-semiconductor layer 14 is prevented more effectively.

In a step of forming a common electrode 22, a first inorganic insulating film 20 is formed on a whole surface of the substrate that includes the source electrode 16 and the drain electrode 17 using CVD, as illustrated in FIG. 9(a). After the first inorganic insulating film 20 is formed, the first inorganic insulating film 20 may be annealed. Next, a material for an organic insulating layer 21 is applied to a whole surface of the substrate that includes the first inorganic insulating film 20 using spin coating or slit coating, for example. An applied film is dried to form an organic insulating film that has a flat surface. The organic insulating film is patterned and then annealed to form an organic insulating layer 21, as illustrated in FIG. 9(b). The annealing is performed at 200° C. for one hour, for example. Then, a second transparent conductive film is formed on a whole surface of the substrate that includes the organic insulating layer 21 using sputtering. A fifth resist is formed on the second transparent conductive film using photolithography. The fifth resist is used as a mask and the second transparent conductive film is wet-etched. The fifth resist is removed to form a common electrode 22, as illustrated in FIG. 9(c). After the common electrode 22 is patterned, the common electrode 22 may be annealed to make the common electrode 22 polycrystalline.

In a step of forming a pixel electrode 25, a second inorganic insulating film 23 is formed on a whole surface of the substrate that includes the common electrode 22 using CVD. Then, a sixth resist is formed on the second inorganic insulating film 23 using photolithography. The sixth resist is used as a mask, and the first inorganic insulating film 20, the organic insulating layer 21, and the second inorganic insulating film 23 are dry-etched to form a third opening 24, as illustrated in FIG. 10(a).

Then, the sixth resist is removed. A third transparent conductive film is formed on a whole surface of the substrate that includes the second inorganic insulating film 23 using sputtering. A seventh resist is formed on the third transparent conductive film using photolithography. The seventh resist is used as a mask and the third transparent conductive film is wet-etched. The seventh resist is removed to form a pixel electrode 25, as illustrated in FIG. 10(b). The pixel electrode 25 is in contact with the drain electrode 17 at the third opening 24. The TFT substrate 1000A is completed through the steps described above.

### Variation 1

FIG. 11 is a schematic plan view around a TFT of a TFT substrate according to Variation 1. FIG. 12 is a schematic cross-sectional view taken along line C-D in FIG. 11. A TFT 100B of a TFT substrate 1000B according to Variation 1 has a similar configuration as that in Embodiment 1 except that an oxide-semiconductor layer 14 is wider than a gate electrode 12 in a plan view, and a first opening 18 and a second opening 19 each overlap an outer edge of the gate electrode 12.

In the TFT substrate 1000B according to Variation 1, an interlayer insulating layer 15 as an etching-stopper layer covers a top and sides of the oxide-semiconductor layer 14, and has a three-layer structure, as in Embodiment 1. Therefore, etching solution does not reach the oxide-semiconductor layer 14 in wet-etching a source electrode 16 and a drain electrode 17, and thus a reliable TFT substrate is obtained.

### Embodiment 2

A TFT substrate 2000 according to Embodiment 2 is a TFT substrate that includes pixel TFTs and a circuit TFT 200 that are formed on one substrate. In Embodiment 2, the pixel TFTs and part or all of a peripheral drive circuit are integrally formed on one substrate. Such a TFT substrate is called a driver-monolithic TFT substrate. In the driver-monolithic TFT substrate, the peripheral drive circuit is disposed in a region (non-display region or frame region) except a region (display region) that includes multiple pixels. For example, a crystalline-silicon TFT that includes a polycrystalline-silicon film as an active layer is used as a TFT that constitutes the peripheral drive circuit (circuit TFT). If oxide-semiconductor TFTs are used as pixel TFTs and a crystalline-silicon TFT is used as the circuit TFT, as described above, less power is used in the display region and the frame region becomes small.

FIG. 13 is a schematic cross-sectional view of a boundary between the display region and a peripheral region of the TFT substrate according to Embodiment 2. In the TFT substrate 2000, each pixel in a display region 1002 includes a pixel TFT, and a non-display region 1001 includes the circuit TFT 200, as illustrated in FIG. 13. The TFT substrate 2000 includes a substrate 11, a base layer 201 formed on a surface of the substrate 11, a pixel TFT 100A formed on the base layer 201, and the circuit TFT 200 formed on the base layer 201. The pixel TFT 100A and the circuit TFT 200 are integrally formed on the substrate 11. Although a TFT 100A described in a TFT substrate 1000A according to Embodiment 1 illustrated in FIGS. 2 and 3 is shown as the pixel TFT, a TFT 100B described in a TFT substrate 1000B according to Comparative Embodiment 1 illustrated in FIGS. 11 and 12 can be used as the pixel TFT.

The circuit TFT 200 includes a crystalline-silicon-semiconductor layer (e.g. low-temperature polycrystalline-silicon layer) 214 formed on the base layer 201, a third inorganic insulating layer 202 that covers the crystalline-silicon-semiconductor layer 214, and a gate electrode 212 disposed on the third inorganic insulating layer 202. Part of the third inorganic insulating layer 202 that is between the crystalline-silicon-semiconductor layer 214 and the gate electrode 212 functions as a gate insulating layer of the circuit TFT 200. A source electrode 216 and a drain electrode 217 are disposed on an insulating layer (gate insulating layer 13 of the pixel TFT 100A) that covers the gate electrode 212 and the crystalline-silicon-semiconductor layer 214. The source electrode 216 and the drain electrode 217 are each in contact with the crystalline-silicon-semiconductor layer 214 at openings that extend through the insulating layer. The circuit TFT 200 may include an interlayer insulating layer 15 that has a three-layer structure, similarly to the pixel TFT 100A.

The third inorganic insulating layer 202 that is the gate insulating layer of the circuit TFT 200 may extend to a region where the pixel TFT is formed. In this case, an oxide-semiconductor layer 12 of the pixel TFT 100A may be formed on the third inorganic insulating layer 202. The circuit TFT 200 and the circuit TFT 200 are covered by a first inorganic insulating film 20 and an organic insulating layer 21.

In FIG. 3, a TFT 100A includes a gate electrode 12 and a gate insulating layer 13 that are formed on an insulating substrate 11. If a TFT 100A is applied to the pixel TFT according to Embodiment 2, however, a base layer 201 and a third inorganic insulating layer 202 may be formed on the insulating substrate 11, and a gate electrode 12 and a gate insulating layer 13 may be formed on the third inorganic insulating layer 202. Further, the base layer 201 and the third inorganic insulating layer 202 may be removed from a region where the pixel TFT 100A is formed, and the gate electrode 12 and the gate insulating layer 13 may be formed on the insulating substrate 11.

In FIG. 13, the circuit TFT 200 has a top-gate structure in which the crystalline-silicon-semiconductor layer 214 is disposed between the gate electrode 212 and the insulating substrate 11. On the other hand, the pixel TFT has a bottom-gate structure in which the gate electrode 12 is disposed between an oxide-semiconductor layer 14 and the substrate 11. Such a structure more effectively limits increase in the number of manufacturing steps and manufacturing cost when the thin-film transistors 100A and 200 are integrally formed on the one substrate 11.

The gate insulating layer 13 of the pixel TFT 100A may extend to a region where the circuit TFT 200 is formed and function as an insulating layer that covers the gate electrode 212 and the crystalline-silicon-semiconductor layer 214 of the circuit TFT 200. In this case, the gate insulating layer 13 may include multiple layers. The gate electrode 212 of the circuit TFT 200 and the gate electrode 12 of the pixel TFT 100A may be formed in the same layer. The source electrode 216 and the drain electrode 217 of the circuit TFT 200 and a source electrode 16 and a drain electrode 17 of the pixel TFT 100A may be formed in the same layer. A phrase “formed in the same layer” means that the gate electrode 212 of the circuit TFT 200 and the gate electrode 12 of the pixel TFT 100A are formed from the same film (conductive film), or the source electrode 216 and the drain electrode 217 of the circuit TFT 200 and the source electrode 16 and the drain electrode 17 of the pixel TFT 100A are formed from the same film (conductive film). Consequently, an increase in the number of manufacturing steps and manufacturing cost is suppressed.

These embodiments described above may appropriately be combined within the spirit of the present invention. A variation on each embodiment may be combined with another embodiment.

### Display Device

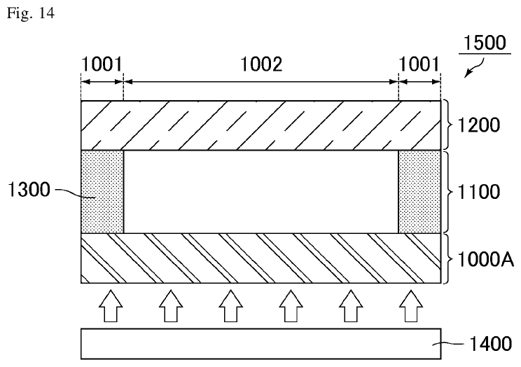

Another aspect of the present invention may be a display device that includes a thin-film transistor substrate according to the present invention. FIG. 14 is a schematic cross-sectional view that illustrates one example of a display device according to the present invention. A display device 1500 illustrated in FIG. 14 is a liquid crystal display device that includes a liquid crystal panel that includes a TFT substrate 1000A, a liquid crystal layer 1100, and a color filter (CF) substrate 1200 that are laminated in this order, and a backlight 1400, for example. The TFT substrate is stuck to the CF substrate with sealant 1300. The TFT substrate may be a TFT substrate 1000A according to Embodiment 1, a TFT substrate 1000B according to Variation 1, or a TFT substrate 2000 according to Embodiment 2.

The CF substrate 1200, the liquid crystal layer 1100, the sealant 1300, and the backlight 1400 may be general ones in a field of liquid crystal display device. The color filter substrate 1200 may include a black matrix in a grid-like shape and a color filter in a grid-like shape that are disposed on a transparent substrate, for example. The color filter or the black matrix is disposed on a region that corresponds to the display region 1002.

The liquid crystal layer 1100 contains liquid crystal molecules. When a voltage that is equal to or higher than a threshold of the liquid crystal molecules is applied to the liquid crystal layer 1100, alignment of the liquid crystal molecules changes, and thus an amount of light the liquid crystal display device transmits is controlled. The liquid crystal molecules preferably are nematic liquid crystal. A liquid-crystal material may have negative anisotropy of dielectric constant or positive anisotropy of dielectric constant.

The sealant 1300 surrounds the display region 1002. The sealant 1300 sticks the TFT substrate 1000A to the CF substrate 1200, and seals the liquid crystal layer 1100 between the TFT substrate 1000A and the CF substrate 1200. The sealant 1300 is not specified but may be thermosetting sealant, light-activated (e.g. ultraviolet-activated) sealant, or thermosetting light-activated sealant.

The display device 1500 may be a transmissive liquid crystal display device that includes a backlight behind the liquid crystal panel. The backlight 1400 may be an edge-light type or a direct type.

An alignment film (not shown) may be disposed between the TFT substrate 1000A and the liquid crystal layer 1100, and may be disposed between the CF substrate 1200 and the liquid crystal layer 1100. The alignment film may be a general one in a field of liquid crystal display device. If the TFT substrate 1000A is a TFT substrate for FFS mode, however, the alignment film is preferably a horizontal alignment film.

In Embodiment 1, a liquid crystal display device is mainly described. Kinds of display devices according to the present invention are not specifically limited to a liquid crystal display device. A display device according to the present invention may be a microencapsulated electrophoretic electronic paper, or an organic or inorganic EL display, for example.

### Comparative Embodiment 1

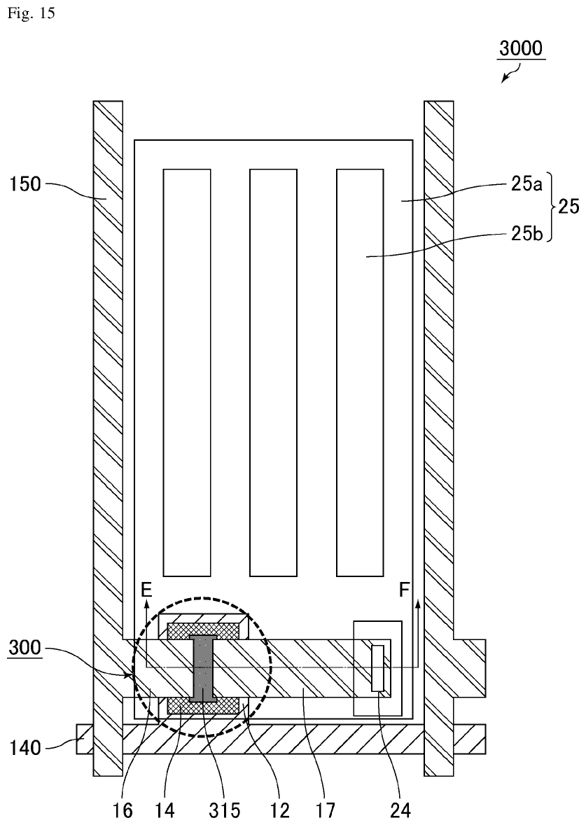

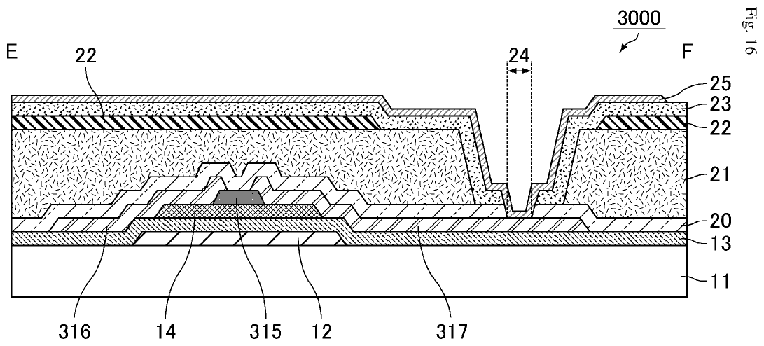

FIG. 15 is a schematic plan view around a TFT of a TFT substrate according to Comparative Embodiment 1. FIG. 16 is a schematic cross-sectional view taken along line E-F in FIG. 15. A TFT substrate 3000 according to Comparative Embodiment 1 has a similar configuration as a TFT substrate 1000A according to Embodiment 1 except that an etching-stopper (ES) layer 315 is disposed in a central portion of an oxide-semiconductor layer 14 (channel region), and an opening is not formed in a region that is over the oxide-semiconductor layer in a plan view, as illustrated in FIG. 15.

In the TFT substrate 3000 according to Comparative Embodiment 1, a source electrode 16 is directly in contact with an oxide-semiconductor layer 14 not through an opening, and a gate electrode 17 is directly in contact with the oxide-semiconductor layer 14 not through an opening, as illustrated in FIG. 16. As in Embodiment 1, the oxide-semiconductor layer 14 is formed on a gate insulating layer 13, and then an ES layer 315 is formed on a whole surface of a substrate that includes the oxide-semiconductor layer 14 using CVD. An eighth resist is formed on a channel region on the oxide-semiconductor layer 14 using photolithography. The ES layer 315 is dry-etched except the ES layer 315 in the channel region. Then the eighth resist is removed. The ES layer may include one layer or two or more layers. A transparent conductive film is formed on the oxide-semiconductor layer 14 and the ES layer 315. Next, a ninth resist is formed on the transparent conductive film using photolithography. The ninth resist is used as a mask and the first transparent conductive film is wet-etched. Then the ninth resist is removed to form a source electrode 16 and a drain electrode 17.

In Comparative Embodiment 1, the ES layer 315 does not cover sides of the oxide-semiconductor layer 14. Therefore, etching solution may reach and etch the oxide-semiconductor layer 14 in a step of forming the source electrode 16 and the drain electrode 17.

Hereinafter, the present invention will be described in more detail based on examples. The examples, however, are not intended to limit the scope of the present invention.

### Example 1

A TFT substrate according to Example 1 is a TFT substrate for FFS mode and has a configuration illustrated in FIGS. 2 and 3. FIG. 2 is a schematic plan view of one pixel of the TFT substrate according to Example 1. FIG. 3 is a schematic cross-sectional view of one pixel of the TFT substrate according to Example 1. In Example 1, a TFT substrate was made using manufacturing steps illustrated in FIGS. 4 to 9.

### Formation of Gate Electrode

A Cu thin film as a gate electrode layer was formed on a glass substrate using sputtering. After a resist was formed using photolithography, the Cu thin film was wet-etched to form a gate bus line and a gate electrode. The obtained gate electrode had a thickness of 300 nm.

### Formation of Gate Insulating Layer

An SiN film was formed on a whole surface of the substrate that included the gate electrode using CVD, and then an SiO₂ film was laminated. An obtained gate insulating layer had a thickness of 400 nm.

### Formation of Oxide-Semiconductor Layer

A semiconductor (In—Ga—Sn—O semiconductor) film that contained indium, gallium, tin, and oxygen was formed on a whole surface of the substrate that included the gate insulating layer using sputtering. A photosensitive resist with a thickness of 2.0 μm was patterned on the semiconductor film using photolithography, and then the oxide-semiconductor film was etched using isotropic etching to form an oxide-semiconductor layer. The obtained oxide-semiconductor layer had a thickness of 50 nm.

### Formation of Interlayer Insulating Layer

An SiO₂ film as a first interlayer insulating layer was formed on a whole surface of the substrate that included the oxide-semiconductor layer using CVD. Then an SiOxNy (e.g. x:y=1:2) film as a second interlayer insulating layer was formed on the SiO₂ film using CVD. Then an SiOxNy film (x:y=1:1) as a third interlayer insulating layer was formed on the SiOxNy film using CVD. Then, a resist was formed using photolithography, and by dry-etching, a first opening and a second opening that extended through the first, second, and third interlayer insulating layers were formed at regions that were over the oxide-semiconductor layer in a plan view. The obtained interlayer insulating layer included the first interlayer insulating layer with a thickness of 20 nm, the second interlayer insulating layer with a thickness of 30 nm, and the third interlayer insulating layer with a thickness of 30 nm. The first, second, and third interlayer insulating layers were formed using plasma CVD that used SiH₄ as a gas source. The SiOxNy used for the second interlayer insulating layer may have x≥1 and y≥2.

### Formation of Source Electrode and Drain Electrode

A Ti film as a source lower-layer electrode and a drain lower-layer electrode was formed on a whole surface of the substrate that included the interlayer insulating layer using sputtering. A Cu film as a source upper-layer electrode and a source upper-layer electrode was formed on the Ti film using sputtering. Then a 2.0-μm photoresist was applied to the Cu film, exposed to light, and developed. Then a source electrode and a drain electrode were formed using wet etching. The wet etching used etching solution that contained 0.1 mol % of hydrogen fluoride (HF). The obtained source electrode and drain electrode each had the lower-layer electrode that was a Ti film with a thickness of 50 nm, and the upper-layer electrode that was a Cu film with a thickness of 200 nm.

### Formation of Common Electrode

An SiO₂ film as a first inorganic insulating film was formed on a whole surface of the substrate that included the source electrode and the drain electrode using CVD. Positive-photosensitive-acrylic-resin composition was applied to the first inorganic insulating film, dried, exposed to light, and developed to form an organic insulating layer. An ITO film was formed on the organic insulating layer using sputtering. A resist was formed using photolithography, and then a common electrode was formed using wet etching. The obtained first inorganic insulating film had a thickness of 200 nm. The obtained organic insulating layer had a thickness of 2.0 μm. The obtained common electrode had a thickness of 80 nm.

### Formation of Pixel Electrode

An SiN film as a second inorganic insulating film was formed on a whole surface of the substrate that included the common electrode using CVD. A resist was formed using photolithography. The first inorganic insulating film, the organic insulating layer, and the second inorganic insulating film were dry-etched to form a third opening. Next, an ITO film was formed on a whole surface of the substrate that included the second inorganic insulating film using sputtering. After a resist was formed using photolithography, a pixel electrode was formed using wet etching. The obtained second inorganic insulating film had a thickness of 200 nm. The obtained pixel electrode had a thickness of 75 nm. As described above, a TFT substrate according to Example 1 was completed.

### Example 2

A TFT substrate according to Example 2 is a concrete example of a TFT substrate according to Embodiment 1 and has a similar configuration as the TFT substrate according to Example 1 except that a structure of an interlayer insulating layer is different. In Example 2, a first interlayer insulating layer was an SiO₂ film with a thickness of 20 nm, a second interlayer insulating layer was an SiOxNy film (e.g. x:y=1:2) with a thickness of 40 nm, and a third interlayer insulating layer was an SiO₂ film with a thickness of 20 nm. The SiOxNy used for the second interlayer insulating layer may have x≥1 and y≥2. The first, second, and third interlayer insulating layers were formed using plasma CVD that used SiH₄ as a gas source.

### Example 3

A TFT substrate according to Example 3 is a concrete example of a TFT substrate according to Embodiment 1 and has a similar configuration as the TFT substrate according to Example 1 except that a structure of an interlayer insulating layer is different. In Example 3, a first interlayer insulating layer was an SiO₂ film with a thickness of 20 nm, a second interlayer insulating layer was an SiOxNy film (e.g. x:y=1:2) with a thickness of 40 nm, and a third interlayer insulating layer was an SiN film with a thickness of 20 nm. The SiOxNy used for the second interlayer insulating layer may have x≥1 and y≥2. The first, second, and third interlayer insulating layers were formed using plasma CVD that used SiH₄ as a gas source.

### Example 4

A TFT substrate according to Example 4 is a concrete example of a TFT substrate according to Embodiment 1 and was similarly made as the TFT substrate according to Example 1 except that a method for making an interlayer insulating layer was different. In Example 4, the first interlayer insulating layer was formed using CVD that used tetraethoxysilane (TEOS) and O₂ or used tetraethoxysilane (TEOS) and O₃. Since the obtained first interlayer insulating layer covered steps well, a second interlayer insulating layer and a third interlayer insulating layer were made thin. In Example 4, the first interlayer insulating layer was an SiO₂ film with a thickness of 20 nm, the second interlayer insulating layer was an SiOxNy film (e.g. x:y=1:2) with a thickness of 30 nm, and the third interlayer insulating layer was an SiN film with a thickness of 10 nm. The SiOxNy used for the second interlayer insulating layer may have x≥1 and y≥2.

### Comparative Example 1

A TFT substrate according to Comparative Example 1 has a similar configuration as the TFT substrate according to Example 1 except that an interlayer insulating layer includes two layers. In Comparative Example 1, an SiO₂ film with a thickness of 20 nm as a first interlayer insulating layer was formed on a whole surface of a substrate that included an oxide-semiconductor layer. Then an SiOxNy film (e.g. x:y=1:2) with a thickness of 60 nm as a second interlayer insulating layer was formed on the SiO₂ film. The SiOxNy used for the second interlayer insulating layer may have x≥1 and y≥2. The first and second interlayer insulating layers were formed using plasma CVD that used SiH₄ as a gas source.

Structures of the interlayer insulating layers of Examples 1 to 4 and Comparative Example 1 are summarized in Table 1 below.

TABLE 1

| | | | | | | Comparative |
|---|---|---|---|---|---|---|
| | | Example 1 | Example 2 | Example 3 | Example 4 | example 1 |
| First interlayer | Composition | SiO₂ | SiO₂ | SiO₂ | SiO₂ | SiO₂ |
| insulating layer | Thickness (nm) | 20 | 20 | 20 | 20 | 20 |
| Second interlayer | Composition | SiOxNy | SiOxNy | SiOxNy | SiOxNy | SiOxNy |
| insulating layer | | (e.g. x:y = | (e.g. x:y = | (e.g. x:y = | (e.g. x:y = | (e.g. x:y = |
| | | 1:2) | 1:2) | 1:2) | 1:2) | 1:2) |
| | Thickness (nm) | 30 | 40 | 40 | 30 | 60 |
| Third interlayer | Composition | SiOxNy | SiO₂ | SiN | SiN | |
| insulating layer | | (e.g. x:y = | | | | |
| | | 1:1) | | | | |
| | Thickness (nm) | 30 | 20 | 20 | 10 | — |

| | | | | | |
|---|---|---|---|---|---|
| Relation between etch rates | ER2 < ER3 < ER1 | ER2 < ER3 − ER1 | ER3 < ER2 < ER1 | ER3 < ER2 < ER1 | ER2 < ER1 |

In the TFT substrate according to Example 1, the interlayer insulating layer as an etching-stopper layer covered a top and sides of the oxide-semiconductor layer, and had a three-layer structure. Therefore, etching solution did not reach and etch the oxide-semiconductor layer when the source electrode and the drain electrode were wet-etched. Therefore, a reliable TFT substrate was obtained. In Examples 2 to 4, etching solution did not reach and etch the oxide-semiconductor layer when the source electrode and the drain electrode were formed.

Therefore, a reliable TFT substrate was obtained, as in Example 1. In Comparative Example 1, the second interlayer insulating layer had a high membrane stress, and thus film adhesion was not sufficient. Therefore, etching solution reached the oxide-semiconductor layer and removed part of the oxide semiconductor when the source electrode and the drain electrode were formed.

### Additional Remarks

One aspect of the present invention may be a thin-film transistor substrate that includes: an insulating substrate; a gate electrode disposed on the insulating substrate; a gate insulating layer that covers the gate electrode; an oxide-semiconductor layer that is disposed on the gate insulating layer and is partly over the gate electrode; an interlayer insulating layer that covers a top and a side of the oxide-semiconductor layer; and a source electrode and a drain electrode that are disposed on the interlayer insulating layer, wherein the interlayer insulating layer includes a first interlayer insulating layer, a second interlayer insulating layer, and a third interlayer insulating layer that are laminated on the oxide-semiconductor layer in this order, and includes a first opening where the source electrode is in contact with the oxide-semiconductor layer and a second opening where the drain electrode is in contact with the oxide-semiconductor layer in regions that are over the oxide-semiconductor layer in a plan view, and an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

In one aspect of the present invention, the etch rate ER1 of the first interlayer insulating layer, the etch rate ER2 of the second interlayer insulating layer, and the etch rate ER3 of the third interlayer insulating layer may have a relation of ER2<ER3≤ER1. If ER2<ER3≤ER1 is satisfied, the third interlayer insulating layer may contain silicon oxide or silicon oxide nitride.

In one aspect of the present invention, the etch rate ER1 of the first interlayer insulating layer, the etch rate ER2 of the second interlayer insulating layer, and the etch rate ER3 of the third interlayer insulating layer may have a relation of ER3<ER2<ER1. If ER3<ER2<ER1 is satisfied, the third interlayer insulating layer may contain silicon nitride or silicon oxide nitride.

In one aspect of the present invention, the oxide-semiconductor layer may contain a semiconductor that contains indium, gallium, zinc, and oxygen, a semiconductor that contains zinc and oxygen, a semiconductor that contains indium, zinc, and oxygen, a semiconductor that contains zinc, titanium, and oxygen, a semiconductor that contains cadmium, germanium, and oxygen, a semiconductor that contains cadmium, lead, and oxygen, a semiconductor that contains cadmium oxide, a semiconductor that contains magnesium, zinc, and oxygen, a semiconductor that contains indium, tin, zinc, and oxygen, or a semiconductor that contains indium, gallium, tin, and oxygen.

In one aspect of the present invention, the first interlayer insulating layer may contain silicon oxide. The second interlayer insulating layer may contain silicon oxide nitride.

Another aspect of the present invention may be a display device that includes a thin-film transistor substrate according to the present invention.

Another aspect of the present invention may be a method for manufacturing a thin-film transistor substrate that has a bottom-gate structure, including the steps of: forming an interlayer insulating layer on an oxide-semiconductor layer; and forming a source electrode and a drain electrode on the interlayer insulating layer, wherein in the forming the interlayer insulating layer, a first interlayer insulating layer is formed to cover the oxide-semiconductor layer, a second interlayer insulating layer is formed on the first interlayer insulating layer, and a third interlayer insulating layer is formed on the second interlayer insulating layer, and part of the first, second, and third interlayer insulating layers is removed at regions that are over the oxide-semiconductor layer in a plan view to form a first opening and a second opening, and in the forming the source electrode and the drain electrode, a conductive film is formed on the interlayer insulating layer, the first opening, and the second opening, and is patterned using wet etching, and an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

In another aspect of the present invention, the etch rate ER1 of the first interlayer insulating layer, the etch rate ER2 of the second interlayer insulating layer, and the etch rate ER3 of the third interlayer insulating layer may have a relation of ER2<ER3≤ER1.

In another aspect of the present invention, the etch rate ER1 of the first interlayer insulating layer, the etch rate ER2 of the second interlayer insulating layer, and the etch rate ER3 of the third interlayer insulating layer may have a relation of ER3<ER2<ER1.

In another aspect of the present invention, the first interlayer insulating layer may be formed using CVD that uses tetraethoxysilane and O₂ or uses tetraethoxysilane and O₃.

In another aspect of the present invention, in the forming a source electrode and a drain electrode, wet etching may be performed using etching solution that contains a hydrogen-fluoride compound.

### REFERENCE SIGNS LIST

11 insulating substrate
12, 212 gate electrode
13 gate insulating layer
14 oxide-semiconductor layer
15 interlayer insulating layer (etching-stopper (ES) layer)
15a first interlayer insulating layer
15b second interlayer insulating layer
15c third interlayer insulating layer
16, 216 source electrode
16a source lower-layer electrode
16b source upper-layer electrode
17, 217 drain electrode
17a drain lower-layer electrode
17b drain upper-layer electrode
18 first opening
19 second opening
20 first inorganic insulating film
21 organic insulating layer
22 common electrode
23 second inorganic insulating film
24 third opening
24 pixel electrode
25a line-shaped electrode
25b opening (slit)
100A, 100B, 300 thin-film transistor (pixel TFT)
110 source driver circuit
120 gate driver circuit
130 inspection circuit
140 gate bus line
150 source bus line
200 thin-film transistor (circuit TFT)
201 base layer
202 third inorganic insulating layer
214 crystalline-silicon-semiconductor layer
315 etching-stopper (ES) layer
1000A, 1000B, 2000, 3000 thin-film transistor (TFT) substrate
1001 non-display region
1002 display region
1100 liquid crystal layer
1200 color filter (CF) substrate
1300 sealant
1400 backlight
1500 display device

1: A thin-film transistor substrate comprising:
an insulating substrate;
a gate electrode disposed on the insulating substrate;
a gate insulating layer that covers the gate electrode;
an oxide-semiconductor layer that is disposed on the gate insulating layer and is partly over the gate electrode;
an interlayer insulating layer that covers a top and a side of the oxide-semiconductor layer; and
a source electrode and a drain electrode that are disposed on the interlayer insulating layer,
wherein the interlayer insulating layer includes a first interlayer insulating layer, a second interlayer insulating layer, and a third interlayer insulating layer that are laminated on the oxide-semiconductor layer in this order, and includes a first opening where the source electrode is in contact with the oxide-semiconductor layer and a second opening where the drain electrode is in contact with the oxide-semiconductor layer in regions that are over the oxide-semiconductor layer in a plan view, and
an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

2: The thin-film transistor substrate according to claim 1,
wherein the etch rate ER1 of the first interlayer insulating layer, the etch rate ER2 of the second interlayer insulating layer, and the etch rate ER3 of the third interlayer insulating layer have a relation of ER2<ER3≤ER1.

3: The thin-film transistor substrate according to claim 2,
wherein the third interlayer insulating layer contains silicon oxide or silicon oxide nitride.

4: The thin-film transistor substrate according to claim 1,
wherein the etch rate ER1 of the first interlayer insulating layer, the etch rate ER2 of the second interlayer insulating layer, and the etch rate ER3 of the third interlayer insulating layer have a relation of ER3<ER2<ER1.

5: The thin-film transistor substrate according to claim 4,
wherein the third interlayer insulating layer contains silicon nitride or silicon oxide nitride.

6: The thin-film transistor substrate according to claim 1,
wherein the oxide-semiconductor layer contains a semiconductor that contains indium, gallium, zinc, and oxygen, a semiconductor that contains zinc and oxygen, a semiconductor that contains indium, zinc, and oxygen, a semiconductor that contains zinc, titanium, and oxygen, a semiconductor that contains cadmium, germanium, and oxygen, a semiconductor that contains cadmium, lead, and oxygen, a semiconductor that contains cadmium oxide, a semiconductor that contains magnesium, zinc, and oxygen, a semiconductor that contains indium, tin, zinc, and oxygen, or a semiconductor that contains indium, gallium, tin, and oxygen.

7: The thin-film transistor substrate according to claim 1,
wherein the first interlayer insulating layer contains silicon oxide.

8: The thin-film transistor substrate according to claim 1,
wherein the second interlayer insulating layer contains silicon oxide nitride.

9: A display device comprising the thin-film transistor substrate according to claim 1.

10: A method for manufacturing a thin-film transistor substrate that has a bottom-gate structure, comprising the steps of:
forming an interlayer insulating layer on an oxide-semiconductor layer; and
forming a source electrode and a drain electrode on the interlayer insulating layer,
wherein in the forming the interlayer insulating layer, a first interlayer insulating layer is formed to cover the oxide-semiconductor layer, a second interlayer insulating layer is formed on the first interlayer insulating layer, a third interlayer insulating layer is formed on the second interlayer insulating layer, and part of the first, second, and third interlayer insulating layers is removed at regions that are over the oxide-semiconductor layer in a plan view to form a first opening and a second opening, and
in the forming the source electrode and the drain electrode, a conductive film is formed on the interlayer insulating layer, the first opening, and the second opening, and is patterned using wet etching, and
an etch rate ER1 at which etching solution etches the first interlayer insulating layer, an etch rate ER2 at which the etching solution etches the second interlayer insulating layer, and an etch rate ER3 at which the etching solution etches the third interlayer insulating layer have relations of ER2<ER1 and ER3≤ER1.

11: The method for manufacturing a thin-film transistor substrate according to claim 10,
wherein the etch rate ER1 of the first interlayer insulating layer, the etch rate ER2 of the second interlayer insulating layer, and the etch rate ER3 of the third interlayer insulating layer have a relation of ER2<ER3≤ER1.

12: The method for manufacturing a thin-film transistor substrate according to claim 10,
wherein the etch rate ER1 of the first interlayer insulating layer, the etch rate ER2 of the second interlayer insulating layer, and the etch rate ER3 of the third interlayer insulating layer have a relation of ER3<ER2<ER1.

13: The method for manufacturing a thin-film transistor substrate according to claim 10,
wherein the first interlayer insulating layer is formed using a CVD method that uses tetraethoxysilane and O₂ or uses tetraethoxysilane and O₃.

14: The method for manufacturing a thin-film transistor substrate according to claim 10,
wherein in the forming the source electrode and the drain electrode, wet etching is performed using etching solution that contains a hydrogen-fluoride compound.
